(19) United States
(12) Patent Application Publication
(10) Pub. No.: US 2025/0385111 A1
(43) Pub. Date: Dec. 18, 2025

(54) Methods and Apparatus for Determining a Property of a Substrate Surface

(71) Applicant: Applied Materials, Inc., Santa Clara, CA (US)

(72) Inventors: Ying WANG, Singapore (SG); Ran XU, Singapore (SG); Raymond HUNG, Palo Alto, CA (US)

(21) Appl. No.: 18/744,807

(22) Filed: Jun. 17, 2024

(51) Int. Cl. H01L 21/67

(52) U.S. Cl. CPC H01L 21/67253; H01L 21/6715

(57) ABSTRACT

A method of determining a property of a substrate surface and a processing chamber configured to determine a property of a substrate are disclosed herein. The method includes flowing a liquid onto a rotating substrate, stopping the flow, and measuring a time for a trailing edge of a liquid layer to move across the rotating substrate to determine the property.

### FIELD

Embodiments of the present disclosure generally relate to methods and apparatus of determining a property of a substrate surface. In particular, a method and apparatus for determining a level of activation of a treated substrate.

### BACKGROUND

Determining and monitoring of the activity of a treated surface of a substrate such as a wafer involves measuring the degree of hydrophilicity of the surface. Determining hydrophilicity is currently achieved by measuring a contact angle of water on the activated surface using a conventional surface analyzer such as a goniometer. However, the inventors have observed that contact angle measurement requires off-line analysis and is thus limited in the number of wafers or other substates which may be sampled during production due to the slow, destructive nature of the testing, and the contamination of the substrate that results from the determination. Current analysis cannot be utilized in a real-time or in an online manner to determine drift or other trends. Further, the subjective nature of the analysis is less accurate and subject to operator interpretation as well as environmental, handling, and other complications.

Thus, the inventors have provided improved methods and apparatus to monitor properties of treated substrates in a real-time manner.

### SUMMARY

Methods and apparatus for determining a property of a substrate surface are provided herein. In some embodiments, a method of determining a property of a substrate surface comprises flowing a liquid onto an upper surface of a rotating substrate proximate to a center axis of the rotating substrate and stopping the flow of the liquid to form a liquid layer on the upper surface having a trailing edge moving across the upper surface of the rotating substrate radially outward from the center axis; determining an analysis time required for the trailing edge to move from a first radius to a second radius of the rotating substrate; and determining a property of the substrate surface based at least in part on the analysis time.

In some embodiments, a method of determining a level of activation of an upper surface of a substrate comprises rotating a substrate about a center axis at greater than or equal to about 50 RPM while flowing a liquid onto an upper surface proximate to the center axis to form a liquid layer on the upper surface of the rotating substrate; stopping the flow of the liquid; directing a gas onto the upper surface proximate to the center axis in amount sufficient to produce a trailing edge of the liquid layer moving radially outward from the center axis of the rotating substrate; determining an analysis time required for the trailing edge to move from a first radius to a second radius of the upper surface of the rotating substrate; and determining the level of activation of the upper surface of the substrate based at least in part on the analysis time using a previously determined calibration comprising analysis times of substrate surfaces having known levels of activation.

In some embodiments, a processing chamber configured for determining a property of a substrate surface comprises a platform configured to rotate a substrate about a center axis of the substrate at a rate of greater than or equal to about 50 RPM; a liquid inlet configured to dispose a liquid onto an upper surface of the rotating substrate and to stop a flow of the liquid onto the upper surface to form a layer of the liquid having a trailing edge moving across the upper surface of the rotating substrate radially outward from the center axis of the rotating substrate; and a detection system configured to determine an analysis time required for the trailing edge of the layer of the liquid to move from a first radius to a second radius across the upper surface of the rotating substrate.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 is a flowchart depicting a method of determining a property of a substrate surface according to an embodiment disclosed herein.

FIG. 2 is a diagram depicting an apparatus for determining a property of a substrate surface according to embodiments disclosed herein.

FIG. 3 is a diagram depicting a processing chamber for determining a property of a substrate surface according to embodiments disclosed herein.

FIG. 4 is a schematic top view depicting a multi-chamber processing tool according to embodiments disclosed herein.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of a method of determining a level of activation of an upper surface of a substrate, and an apparatus for determining a level of activation of an upper surface of a substrate are provided herein.

In embodiments, a method of determining a property of a substrate surface comprises flowing a liquid onto an upper surface of a rotating substrate proximate to a center axis of the rotating substrate. Then stopping the flow of the liquid to form a liquid layer on the upper surface having a trailing edge moving across the upper surface of the rotating substrate radially outward from the center axis. Accordingly, an aliquot of the liquid is disposed onto the upper surface of the rotating substrate which forms a layer of the liquid having a trailing edge moving across the upper surface of the rotating substrate radially outward from the center axis. Next, the method includes determining an analysis time required for the trailing edge to move from a first radius to a second radius of the rotating substrate, followed by determining a property of the substrate surface based at least in part on the analysis time.

The inventors have observed that a well-activated surface suitable for hybrid bonding applications, and the like, is hydrophilic having a low contact angle to water, i.e., less than about 5 degrees. The inventors have further observed that the more hydrophilic the surface is, the longer is time required for a trailing edge of a layer of water to move from the center of a spinning substrate to a defined radius from the center.

The movement of the trailing edge can be captured by a camera, or determined using another detector, and the time, referred to herein as the analysis time, recorded. A property of the substrate surface, e.g., a hydrophilicity of the substrate, can be determined by comparing the determined analysis time of a subject substrate with analysis times of substrates having known properties which have been previously analyzed in the same way of the subject substrate.

In embodiments, the method further comprises directing an amount of a gas onto the upper surface of the rotating substrate proximate to the center axis sufficient to produce the trailing edge of the liquid layer. In other words, a jet of gas is directed onto the upper surface to break the surface tension of the liquid and form a dry spot, thereby forming the trailing edge of the liquid layer which then progresses across the surface of the rotating substrate.

In embodiments, determining the analysis time comprises an optical determination. In some embodiments, the determining of the analysis time comprises a change in a reflectance of a laser beam off of the substrate surface at one or both of the first radius and the second radius. In some embodiments, determining the analysis time comprises measuring a refractive index of the substrate surface at one or both of the first radius and the second radius.

In embodiments, the liquid comprises an indicator, and the determining of the analysis time comprises determining whether or not the indicator is present at one or both of the first radius and the second radius. In embodiments, the determining of the analysis time comprises measuring a change in a capacitance of the substrate. In embodiments, the determining of the analysis time comprises measuring a change in an electrical conductivity of the substrate. In embodiments, the determining of the analysis time comprises measuring a change in thickness of the surface brought about by either a presence or an absence of the fluid layer on the surface. In embodiments, the thickness is measured and/or detected by a non-contacting thickness measurement tool such as a confocal chromatic sensor or other optical device pointing towards the top surface of substrate.

In embodiments, the property of the substrate surface is determined using a previously determined calibration comprising analysis times of a plurality of substrate surfaces having known properties.

In embodiments, the liquid comprises water, or in embodiments, the liquid is water, and the determined property of the substrate surface is a hydrophilicity of the substrate surface.

In embodiments, the liquid comprises an organic solvent, and the determined property of the substrate surface comprises a hydrophobicity of the substrate surface.

In embodiments, the substrate is rotated at greater than or equal to about 50 rpm, and less than or equal to about 2500 rpm.

In embodiments, the first radius is from about 5% to about 15% of a total radius of the substrate, and the second radius is from about 50% to about 95% of the total radius of the substrate.

In embodiments, a plurality of analysis times are determined for the same substrate using a plurality of first radii to a corresponding second radii of the rotating substrate; and determining a property of the substrate surface based at least in part on the plurality of analysis times.

In embodiments, the determining of the analysis time is conducted within a processing chamber, which in embodiments is a wet-clean processing chamber, which in embodiments is a component or module of a multi-chamber processing tool. In some embodiments, the processing chamber is utilized to determine the analysis time is a stand-alone spinning tool.

In embodiments, the determining of the analysis time is conducted within a processing chamber of a multi-chamber processing tool after treatment of the upper surface of the substrate within another processing chamber of the multi-chamber processing tool without removing the substrate from the multi-chamber processing tool prior to the determining of the analysis time.

In some embodiments, a method of determining a level of activation of an upper surface of a substrate, comprises disposing an aliquot of an aqueous liquid onto the upper surface of the substrate being rotated about a center axis at greater than or equal to about 50 rpm to form a layer of the liquid thereon; directing a gas onto the rotating upper surface of the substrate proximate to the center axis in amount sufficient to produce a trailing edge of the liquid layer moving radially outward from the center of the substrate; determining an analysis time required for the trailing edge to move from a first radius to a second radius of the rotating upper surface of the substrate; and determining the level of activation of the upper surface of the substrate based at least in part on the analysis time using a previously determined calibration comprising analysis times of substrate surfaces having known levels of activation.

In embodiments, determining the analysis time comprises an optical determination utilizing a video camera. In embodiments, the liquid comprises an indicator, and the determining the analysis time comprises determining whether or not the indicator is present at the first radius and the second radius.

In embodiments, a clean processing chamber for determining a property of a substrate surface comprises a platform configured to rotate a substrate about a center axis of the substrate at a rate of greater than or equal to about 50 RPM; a liquid inlet configured to dispose a liquid onto an upper surface of the rotating substrate and to stop a flow of the liquid onto the upper surface to form a layer of the liquid having a trailing edge moving across the upper surface of the rotating substrate radially outward from the center axis of the rotating substrate; and a detection system configured to determine an analysis time required for the trailing edge of the liquid layer to move from a first radius to a second radius across the upper surface of the rotating substrate. In embodiments, the processing chamber further comprises a gas inlet configured to direct a flow of gas onto the upper surface of the rotating substrate in amount sufficient to produce the trailing edge of the liquid layer.

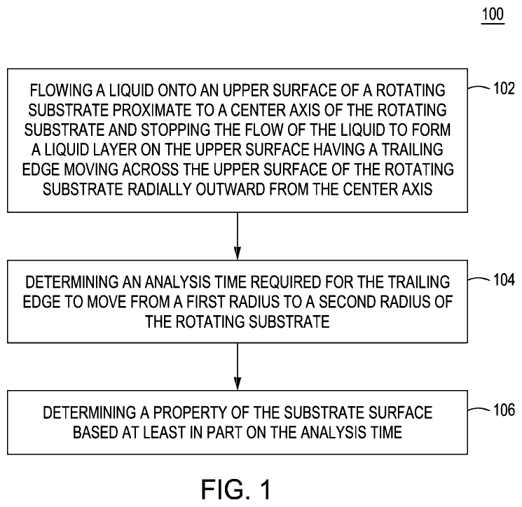

FIG. 1 is a diagram depicting a flow chart of a method 100 according to an embodiment of the instant disclosure. The method 100 includes flowing a liquid onto an upper surface of a rotating substrate proximate to a center axis of the rotating substrate and stopping the flow of the liquid to form a liquid layer on the upper surface having a trailing edge moving across the upper surface of the rotating substrate radially outward from the center axis (block 102). The method 100 further includes determining an analysis time required for the trailing edge to move from a first radius to a second radius of the rotating substrate (block 104), followed by determining a property of the substrate surface based at least in part on the analysis time (block 106). In embodiments, method 100 may include additional blocks.

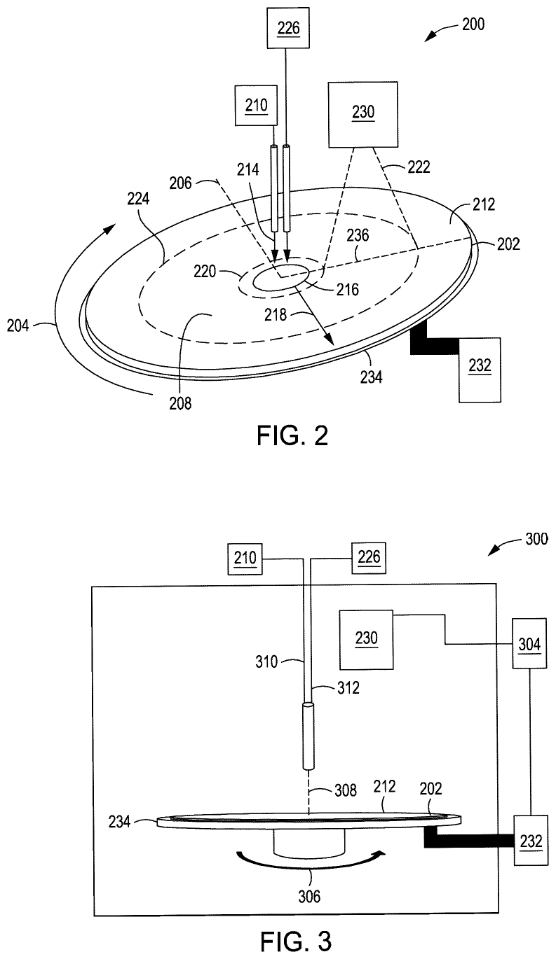

FIG. 2 is a block diagram depicting an apparatus 200 for conducting the method according to embodiments disclosed herein. In embodiments, the rotating substrate 202 is rotated 204 about a center axis 206. An aliquot, e.g., a portion of a liquid 210 is disposed onto the substrate surface 212 of the rotating substrate 202 proximate to the center axis 206. The disposing of the aliquot of the liquid 210 is characterized by starting a flow 214 of the liquid 210 and then stopping the flow 214 of the liquid 210 onto the substrate surface 212 of the rotating substrate 202 thereby forming a layer 208 of the liquid 210 having a trailing edge 216 moving across the substrate surface 212 of the rotating substrate 202 radially outward 218 from the center axis 206 via the centripetal force acting on the layer 208 due to the rotation 204. An analysis time required for the trailing edge 216 to move from a first radius 220 to a second radius 224 of the rotating substrate 202. The analysis time is then correlated with analysis times of substrate surfaces having known properties which have been analyzed under the same conditions to determine the property of the substrate surface.

The disposing of the aliquot of the liquid 210 onto the upper surface of the rotating substrate may initially form a layer 208 lacking the trailing edge 216 due to the surface tension of the liquid and other factors. To reduce analysis time and improve precision, in embodiments, the method further comprises directing an amount of a gas 226 onto the substrate surface 212 of the rotating substrate 202 proximate to the center axis 206 sufficient to dry or otherwise break the surface tension of the layer 208 of the liquid 210 to form the trailing edge 216.

In embodiments, the determining of the analysis time comprises using an optical sensor 230 to determine the analysis time. In embodiments, the optical sensor 230 includes a video camera. In some embodiments, the determining of the analysis time comprises a change in a reflectance of a laser beam 222 resultant from the trailing edge 216 passing over the substrate surface at one or both of the first radius 220 and the second radius 224. In some embodiments, determining the analysis time comprises measuring a refractive index of the substrate surface 212 at one or both of the first radius 220 and the second radius 224 utilizing the optical sensor 230 to determine the time at which the trailing edge 216 passes over the substrate surface at one or both of the first radius 220 and the second radius 224.

In embodiments, the liquid comprises an indicator, e.g., a dye, a fluorescent indicator, and/or the like, which is detectable by the optical sensor 230, and the determining of the analysis time comprises determining whether or not the indicator is present at one or both of the first radius 220 and the second radius 224 by the optical sensor 230.

In some embodiments, determining the analysis time comprises measuring a change in a capacitance of the substrate, or a change in an electrical conductivity of the substrate utilizing a non-contact sensor, e.g., optical sensor 230, or a contact sensor 232 in physical contact with the rotating substrate 202, or a platform 234 on which the rotating substrate 202 is disposed.

In embodiments, a method of determining a level of activation of a substrate surface 212 comprises disposing an aliquot of an aqueous liquid 210 onto the substrate surface 212 of the rotating substrate 202, being rotated 204 about the center axis 206 at greater than or equal to about 50 rpm to form a layer 208 of the liquid 210 thereon, followed by directing a gas 226 onto the substrate surface 212 of the rotating substrate 202 proximate to the center axis 206 in amount sufficient to produce the trailing edge 216 of the layer 208 of the liquid 210 moving radially outward 218 from the center of the rotating substrate 202, and determining an analysis time required for the trailing edge 216 to move from the first radius 220 to the second radius 224 of the upper substrate surface 212 of the rotating substrate 202, and determining the level of activation of the substrate surface 212 based at least in part on the analysis time using a previously determined calibration comprising analysis times obtained in essentially the same way of substrate surfaces having known levels of activation. In some of such embodiments, the analysis time is determined with an optical sensor 230 utilizing a video camera.

In embodiments, the liquid comprises, consists essentially of, or consists of water. In embodiments, the determined property of the substrate surface 212 is a hydrophilicity of the substrate surface 212, which is related to activation of the substrate surface during processing.

In embodiments, the liquid comprises an organic solvent, and the determined property of the substrate surface comprises a hydrophobicity of the substrate surface.

In embodiments, the substrate is rotated at greater than or equal to about 50 rpm. In embodiments, the substrate is rotated at less than or equal to about 2500 rpm. In embodiments, the first radius 220 is located from about 5% to about 15% of a total radius 236 of the substrate surface 212, and the second radius is located from about 50% to about 95% of the total radius 236 of the substrate surface 212.

In other embodiments, the presence or absence of the trailing edge may be determined, at multiple radii such as from about 5% to 10%, again from about 10% to 15%, again from about 15% to 20%, and again from about 20% to 25%, and/or the like, and the property of the substrate surface is determined, e.g., a level of activation of the substrate surface 212, based at least in part on the plurality of analysis times using a previously determined calibration comprising analysis times obtained in essentially the same way of substrate surfaces having known levels of activation.

For example, the analysis time may be determined in a plurality of iterations, from 5%-10%, 10-15%, 15-20%, and 20-25%, and the property of the substrate may be determined either for the entire substrate, or for particular sections of the same substrate. In embodiments, a local or radius-based surface property or surface property profile can be determined for each substrate. In embodiments, a plurality of analysis times are determined for the same substrate using a plurality of first radii to a corresponding second radii of the rotating substrate. For example, a first analysis time is determined from a first radius to a corresponding second radius, a second analysis time is determined from a third radius to a corresponding fourth radius, and so on. In embodiments, the second radius is the same as the third radius, e.g., the first analysis time is determined from the first radius to the second radius, and the second analysis time is determined from the second radius to a subsequent radius, which in the instant example is the fourth radius.

Accordingly, a plurality of first radii to a corresponding second radii refers to subsequent concentric radii where the first radii is less than the second radii used to determine the particular analysis time. In embodiments, the property of the substrate surface is determined based at least in part on one or more of the plurality of analysis times.

FIG. 3 is a block diagram depicting a processing chamber 300 for determining a property of a substrate surface. In embodiments, the processing chamber 300 may be a wet-clean processing chamber, may be a module, component, or part of a multi-chamber processing tool, or may be a stand-alone processing chamber. In embodiments, processing chamber 300 comprises an enclosure 302 comprising a platform 234 configured to rotate 306 a substrate disposed thereon, e.g., rotating substrate 202 about a center axis 308 of the platform 234 at a rate of greater than or equal to about 50 RPM. The processing chamber 300 further comprises a liquid inlet 310 configured to dispose an aliquot of a liquid 210 onto an upper surface of a substrate disposed on the platform 234, e.g., a rotating substrate 202 to form a layer of the liquid having a trailing edge moving across the upper surface of the rotating substrate radially outward from the center axis of the rotating substrate; and an optical sensor 230 and/or a contact sensor 232 configured to determine an analysis time required for the trailing edge of the liquid layer to move from a first radius to a second radius across the upper surface of the rotating substrate (see FIG. 2). In embodiments, the processing chamber 300 further includes a controller 304 to control the flow of the liquid and/or gas, the rotation of the platform, and to receive and process inputs from the optical sensor 230 and/or the contact sensor 232 forming a detection system configured to determine the analysis time and the property of the substrate.

In embodiments, the processing chamber 300 further comprises a gas inlet 312 configured to direct a flow of gas 226 onto the substrate surface 212 of the rotating substrate 202 in amount sufficient to produce the trailing edge of the liquid layer (see FIG. 2).

In embodiments, the processing chamber 300 is a module integrated into, and/or a component of, and connected to a transfer chamber of a multi-chamber processing tool, also referred to as a cluster system or other tool. In other embodiments, the processing chamber 300 is a stand-alone module or apparatus.

In embodiments, the processing chamber 300 is configured as an inline wafer-base monitor of post-activation surface for hydrophilicity during processing, before bonding or other processing.

In embodiments, the processing chamber 300 is configured for use in a hybrid bonding processing system, wherein a dielectric surface is activated by an activation process such as via plasma activation. The processing chamber 300 according to embodiments disclosed herein may be utilized as an in-line analyzer/process monitor, thereby replacing to need to remove a representative substrate for determining water contact angle via a stand-alone metrology tool such as a goniometer or surface analyzer. In embodiments, the processing chamber is utilized downstream of an activation chamber, which may be a dry and/or a wet process.

In some embodiments, a processing chamber configured for determining a property of a substrate surface comprises a platform configured to rotate a substrate about a center axis of the substrate at a rate of greater than or equal to about 50 RPM; a liquid inlet configured to dispose a liquid onto an upper surface of the rotating substrate and to stop a flow of the liquid onto the upper surface to form a layer of the liquid having a trailing edge moving across the upper surface of the rotating substrate radially outward from the center axis of the rotating substrate; and a detection system configured to determine an analysis time required for the trailing edge of the layer of the liquid to move from a first radius to a second radius across the upper surface of the rotating substrate. In embodiments, the processing chamber is a component of, and connected to a transfer chamber of a multi-chamber processing tool.

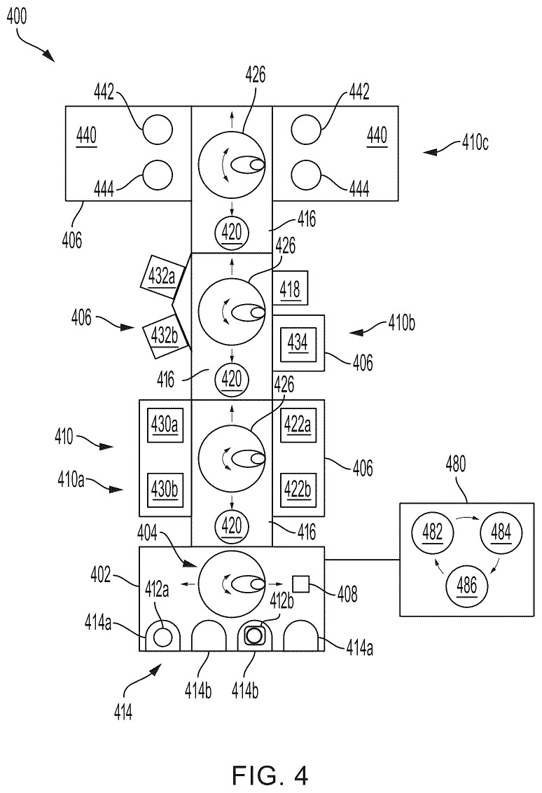

FIG. 4 depicts a schematic top view of a multi-chamber processing tool 400 suitable for use with embodiments disclosed herein. The multi-chamber process tool 400 generally includes an equipment front end module (EFEM) 402 and a plurality of automation modules 410 that are serially coupled to the EFEM 402. The plurality of automation modules 410 are configured to shuttle one or more types of substrates 412 from the EFEM 402 through the multi-chamber process tool 400 and perform one or more processing steps to the one or more types of substrates 412. Each of the plurality of automation modules 410 generally include a transfer chamber 416 and one or more process chambers 406 coupled to the transfer chamber 416 to perform the one or more processing steps. The plurality of automation modules 410 are coupled to each other via their respective transfer chamber 416 to advantageously provide modular expandability and customization of the multi-chamber process tool 400. As depicted in FIG. 4, the plurality of automation modules 410 comprise three automation modules, where a first automation module 410a is coupled to the EFEM 402, a second automation module 410b is coupled to the first automation module 410a, and a third automation module 410c is coupled to the second automation module 410b.

The EFEM 402 includes a plurality of loadports 414 for receiving one or more types of substrates 412. In some embodiments, the one or more types of substrates 412 include 200 mm wafers, 300 mm wafers, 450 mm wafers, tape frame substrates, carrier substrates, silicon substrates, glass substrates, or the like. In some embodiments, the plurality of loadports 414 include at least one of one or more first loadports 414a for receiving a first type of substrate 412a or one or more second loadports 414b for receiving a second type of substrate 412b. In some embodiments, the first type of substrates 412a have a different size than the second type of substrates 412b. In some embodiments, the second type of substrates 412b include tape frame substrates or carrier substrates. In some embodiments, the second type of substrates 412b include a plurality of chiplets disposed on a tape frame or carrier plate. In some embodiments, the second type of substrates 412b may hold different types and sizes of chiplets. As such, the one or more second loadports 414b may have different sizes or receiving surfaces configured to load the second type of substrates 412b having different sizes.

In some embodiments, the plurality of loadports 414 are arranged along a common side of the EFEM 402. Although FIG. 4 depicts a pair of the first loadports 414a and a pair of the second loadports 414b, the EFEM 402 may include other combinations of loadports such as one first loadport 414a and three second loadports 414b.

In some embodiments, the EFEM 402 includes a scanning station 408 having substrate ID readers for scanning the one or more types of substrates 412 for identifying information. In some embodiments, the substrate ID readers include a bar code reader or an optical character recognition (OCR) reader. The multi-chamber processing tool 400 is configured to use any identifying information from the one or more types of substrates 412 that are scanned to determine process steps based on the identifying information, for example, different process steps for the first type of substrates 412a and the second type of substrates 412b. In some embodiments, the scanning station 408 may also be configured for rotational movement to align the first type of substrates 412a or the second type of substrates 412b. In some embodiments, the one or more of the plurality of automation modules 410 include a scanning station 408.

An EFEM robot 404 is disposed in the EFEM 402 and configured to transport the first type of substrates 412a and the second type of substrates 412b between the plurality of loadports 414 to the scanning station 408. The EFEM robot 404 may include substrate end effectors for handling the first type of substrates 412a and second end effectors for handling the second type of substrates 412b. The EFEM robot 404 may rotate or rotate and move linearly.

As shown in FIG. 4, the one or more process chambers 406 may be sealingly engaged with the transfer chamber 416. The transfer chamber 416 generally operates at atmospheric pressure but may be configured to operate at vacuum pressure. For example, the transfer chamber 416 may be a non-vacuum chamber configured to operate at an atmospheric pressure of about 700 Torr or greater. Additionally, while the one or more process chambers 406 are generally depicted as orthogonal to the transfer chamber 416, the one or more process chambers 406 may be disposed at an angle with respect to the transfer chamber 416 or a combination of orthogonal and at an angle. For example, the second automation module 410b depicts a pair of the one or more process chambers 406 disposed at an angle with respect to the transfer chamber 416.

The transfer chamber 416 includes a buffer 420 configured to hold one or more first type of substrates 412a. In some embodiments, the buffer 420 is configured to hold one or more of the first type of substrates 412a and one or more of the second type of substrates 412b. The transfer chamber 416 includes a transfer robot 426 configured to transfer the first type of substrates 412a and the second type of substrates 412b between the buffer 420, the one or more process chambers 406, and a buffer disposed in an adjacent automation module of the plurality of automation modules 410. For example, the transfer robot 426 in the first automation module 410a is configured to transfer the first type of substrates 412a and the second type of substrates 412b between the first automation module 410a and the buffer 420 in the second automation module 410b. In some embodiments, the buffer 420 is disposed within the interior volume of the transfer chamber 416, advantageously reducing the footprint of the overall tool. In addition, the buffer 420 can be open to the interior volume of the transfer chamber 416 for ease of access by the transfer robot 426.

The one or more process chambers 406 may include atmospheric chambers that are configured to operate under atmospheric pressure and vacuum chambers that are configured to operate under vacuum pressure. Examples of the atmospheric chambers may generally include wet-clean chambers, radiation chambers, heating chambers, metrology chambers, bonding chamber, or the like. Examples of vacuum chambers may include plasma chambers. The types of atmospheric chambers discussed above may also be configured to operate under vacuum, if needed. The one or more process chambers 406 may be any process chambers or modules needed to perform a bonding process, a dicing process, a cleaning process, a plating process, or the like.

In some embodiments, the one or more process chambers 406 of each of the plurality of automation modules 410 include at least one of a wet-clean chamber, e.g., wet-clean chamber 422a and wet-clean chamber 422b, a plasma chamber, e.g., plasma chamber 430a and plasma chamber 430b, a degas chamber, e.g., degas chamber 432a and degas chamber 432b, a radiation chamber 434, and a bonder chamber 440.

In embodiments, the wet-clean chamber 422a and/or the wet-clean chamber 422b is configured according to embodiments disclosed herein, to determine an analysis time according to embodiments disclosed herein, in addition to being configured to perform a wet-clean process to clean the one or more types of substrates e.g., substrates 412a and substrates 412b via a fluid, such as water. The first wet-clean chamber 422a may be configured for cleaning the first type of substrates 412a and the second wet-clean chamber 422b for cleaning the second type of substrates 412b.

The degas chamber 432a and the degas chamber 432a are configured to perform a degas process to remove moisture from the substrates 412a and 412b via, for example, a high temperature baking process. In some embodiments, the first degas chamber 432a is configured for the first type of substrates 412a and a second degas chamber 432b for the second type of substrates 412b.

The plasma chamber 430a and plasma chamber 430b may be configured to perform an etch process to remove unwanted material, for example organic materials and oxides, from the first type of substrates 412a or the second type of substrates 412b. In some embodiments, the first plasma chamber 430a is configured for the first type of substrates 412a and a second plasma chamber 430b for the second type of substrates 412b. The plasma chamber 430a and 430b may also be configured to perform an etch process to dice the substrates 412 into chiplets. In some embodiments, the plasma chamber 430 may be configured to perform a deposition process, for example, a physical vapor deposition process, a chemical vapor deposition process, or the like, to coat the first type of substrates 412a or the second type of substrates 412b with a desired layer of material.

The radiation chamber 434 is configured to perform a radiation process on the substrates. For example, the radiation chamber 434 may be an ultraviolet radiation chamber configured to direct ultraviolet radiation or a heating chamber configured to heat portions of the substrate 412.

The bonder chamber 440 is configured to transfer and bond at least a portion of the plurality of chiplets to one of the first type of substrates 412a. The bonder chamber 440 generally includes a first support 442 to support one of the first type of substrates 412a and a second support 444 to support one of the second type of substrates 412b.

In some embodiments, the one or more process chambers 406 of the first automation module 410a includes at least one of a plasma chamber 430 or a degas chamber 432 and includes a wet-clean chamber 422. In the illustrative example of FIG. 4, the first automation module 410a includes a first plasma chamber 430a and a second plasma chamber 430b on a first side of the first automation module 410a. In some embodiments, the first automation module 410a includes a first wet-clean chamber 422a and a second wet-clean chamber 422b on a second side of the first automation module 410a opposite the first side. In some embodiments, the second automation module includes a radiation chamber 434 and at least one of a plasma chamber 430 or a degas chamber 432.

In some embodiments, a last automation module of the plurality of automation module 410, for example the third automation module 410c of FIG. 4, includes one or more bonder chambers 440 (two shown in FIG. 4). In some embodiments, a first of the two bonder chambers is configured to remove and bond chiplets having a first size and a second of the two bonder chambers is configured to remove and bond chiplets having a second size. In some embodiments, any of the plurality of automation modules 410 include a metrology chamber 418 configured to take measurements of the one or more types of substrates 412. In FIG. 4, the metrology chamber 418 is shown as a part of the second automation module 410b coupled to the transfer chamber 416 of the second automation module 410b. However, the metrology chamber 418 may be coupled to any transfer chamber 416 or within the transfer chamber 416.

A controller 480 controls the operation of any of the multi-chamber processing tools described herein, including the multi-chamber processing tool 400. The controller 480 may use a direct control of the multi-chamber processing tool 400, or alternatively, by controlling the computers (or controllers) associated with the multi-chamber processing tool 400. In operation, the controller 480 enables data collection and feedback from the multi-chamber processing tool 400 to optimize performance of the multi-chamber processing tool 400. The controller 480 generally includes a Central Processing Unit (CPU) 482, a memory 484, and a support circuit 486. The CPU 482 may be any form of a general-purpose computer processor that can be used in an industrial setting. The support circuit 486 is conventionally coupled to the CPU 482 and may comprise a cache, clock circuits, input/output subsystems, power supplies, and the like. Software routines, such as a method as described below may be stored in the memory 484 and, when executed by the CPU 482, transform the CPU 482 into a specific purpose computer (controller 480). The software routines may also be stored and/or executed by a second controller (not shown) that is located remotely from the multi-chamber processing tool 400.

The memory 484 is in the form of computer-readable storage media that contains instructions, when executed by the CPU 482, to facilitate the operation of the semiconductor processes and equipment. The instructions in the memory 484 are in the form of a program product such as a program that implements the method of the present principles. The program code may conform to any one of a number of different programming languages. In one example, the disclosure may be implemented as a program product stored on a computer-readable storage media for use with a computer system. The program(s) of the program product define functions of the aspects (including the methods described herein). Illustrative computer-readable storage media include, but are not limited to: non-writable storage media (e.g., read-only memory devices within a computer such as CD-ROM disks readable by a CD-ROM drive, flash memory, ROM chips, or any type of solid-state non-volatile semiconductor memory) on which information is permanently stored; and writable storage media (e.g., floppy disks within a diskette drive or hard-disk drive or any type of solid-state random access semiconductor memory) on which alterable information is stored. Such computer-readable storage media, when carrying computer-readable instructions that direct the functions of the methods described herein, are aspects of the present principles.

Methods and the wet-clean or other processing chamber according to embodiments disclosed herein allow for real time monitoring of surface activity, e.g., hydrophilicity, on each and every processed substrate without having to expose the substrate to an outside environment or remove the substrate from a processing platform. Indeed, methods according to embodiments disclosed herein may be incorporated into cleaning and other processing of substrates after activation. For example, a stand-alone spinning tool such as a spin coater and/or the like may be modified to conduct the method according to embodiments disclosed herein using a solvent on a substrate to determine a surface condition directed to photoresist adherence to the substrate and/or the like, prior to photoresist coating or other processing of the substrate.

Processing of a substrate may include surface activation, followed by transfer of the substrate into a wet-clean chamber and/or other processing chamber of a multi-chamber processing tool according to embodiments disclosed herein, wherein the substrate is processed according to methods disclosed herein, and the suitability of the surface activation is determined without removing the substrate from the multi-chamber processing tool, in real time thus preventing yield loss and wafer scrapping that may result from external testing.

Embodiments disclosed herein find utility in hybrid bonding applications, wherein surface activation of the substrate is required, as well as reduce possible sources of surface contamination, which degrades activation of substrate surfaces.

While the foregoing is directed to embodiments of the present disclosure, other and further embodiments of the disclosure may be devised without departing from the basic scope thereof.

1. A method of determining a property of a substrate surface of a substrate, comprising:
flowing a liquid onto an upper surface of a rotating substrate proximate to a center axis of the rotating substrate and stopping the flow of the liquid to form a liquid layer on the upper surface having a trailing edge moving across the upper surface of the rotating substrate radially outward from the center axis;
determining an analysis time required for the trailing edge to move from a first radius to a second radius of the rotating substrate; and
determining a property of the substrate surface based at least in part on the analysis time.

2. The method of claim 1, further comprising directing an amount of a gas onto the upper surface of the rotating substrate proximate to the center axis sufficient to produce the trailing edge of the liquid layer.

3. The method of claim 1, wherein determining the analysis time comprises an optical determination.

4. The method of claim 1, wherein the determining the analysis time comprises a change in a reflectance of a laser beam off of the substrate surface at one or both of the first radius and the second radius.

5. The method of claim 1, wherein determining the analysis time comprises measuring a refractive index and/or a change in thickness of the substrate at one or both of the first radius and the second radius.

6. The method of claim 1, wherein the liquid comprises an indicator, and wherein determining the analysis time comprises determining whether or not the indicator is present at one or both of the first radius and the second radius.

7. The method of claim 1, wherein the determining the analysis time comprises measuring a change in a capacitance of the substrate, an electrical conductivity of the substrate, or a combination thereof.

8. The method of claim 1, wherein a plurality of analysis times are determined for the same substrate using a plurality of first radii to a corresponding second radii of the rotating substrate; and
determining a property of the substrate surface based at least in part on the plurality of analysis times.

9. The method of claim 1, wherein the property of the substrate surface is determined using a previously determined calibration comprising analysis times of a plurality of substrate surfaces having known properties.

10. The method of claim 1, wherein the liquid comprises water, and wherein the determined property of the substrate surface is a hydrophilicity of the substrate surface.

11. The method of claim 1, wherein the liquid comprises an organic solvent, and wherein the determined property of the substrate surface comprises a hydrophobicity of the substrate surface.

12. The method of claim 1, wherein the substrate is rotated at greater than or equal to about 50 rpm, and less than or equal to about 2500 rpm.

13. The method of claim 1, wherein the first radius is from about 5% to about 15% of a total radius of the substrate, and the second radius is from about 50% to about 95% of the total radius of the substrate.

14. The method of claim 1, wherein the determining of the analysis time is conducted within a wet-clean processing chamber and/or a stand-alone spinning tool.

15. The method of claim 1, wherein the determining of the analysis time is conducted within a processing chamber of a multi-chamber processing tool after treatment of the upper surface of the substrate within another processing chamber of the multi-chamber processing tool without removing the substrate from the multi-chamber processing tool prior to the determining of the analysis time.

16. A method of determining a level of activation of an upper surface of a substrate, comprising:
rotating a substrate about a center axis at greater than or equal to about 50 RPM while flowing a liquid onto an upper surface proximate to the center axis to form a liquid layer on the upper surface of the rotating substrate;
stopping the flow of the liquid;
directing a gas onto the upper surface proximate to the center axis in amount sufficient to produce a trailing edge of the liquid layer moving radially outward from the center axis of the rotating substrate;
determining an analysis time required for the trailing edge to move from a first radius to a second radius of the upper surface of the rotating substrate; and
determining the level of activation of the upper surface of the substrate based at least in part on the analysis time using a previously determined calibration comprising analysis times of substrate surfaces having known levels of activation.

17. The method of claim 16, wherein determining the analysis time comprises an optical determination utilizing a video camera.

18. The method of claim 16, wherein the liquid comprises an indicator, and wherein the determining the analysis time comprises determining whether or not the indicator is present at the first radius and the second radius.

19. A processing chamber configured for determining a property of a substrate surface, comprising:
a platform configured to rotate a substrate about a center axis of the substrate at a rate of greater than or equal to about 50 RPM;
a liquid inlet configured to dispose a liquid onto an upper surface of the rotating substrate and to stop a flow of the liquid onto the upper surface to form a layer of the liquid having a trailing edge moving across the upper surface of the rotating substrate radially outward from the center axis of the rotating substrate; and
a detection system configured to determine an analysis time required for the trailing edge of the layer of the liquid to move from a first radius to a second radius across the upper surface of the rotating substrate.

20. The processing chamber of claim 19, wherein the processing chamber is a component of, and connected to a transfer chamber of a multi-chamber processing tool.
